(19) United States
(12) Patent Application Publication
(10) Pub. No.: US 2003/0001981 A1
(43) Pub. Date: Jan. 2, 2003

(54) Modular digital television architecture

(75) Inventor: James R. Milne, Ramona, CA (US)

Correspondence Address: FITCH EVEN TABIN AND FLANNERY, 120 SOUTH LA SALLE STREET, SUITE 1600, CHICAGO, IL, 60603-3406, US

(73) Assignee: Sony Corporation

(21) Appl. No.: 10/112,228

(22) Filed: Mar. 28, 2002

Related U.S. Application Data
(63) Continuation-in-part of application No. 09/862,391, filed on May 21, 2001.
(60) Provisional application No. 60/335,575, filed on Oct. 22, 2001.

(51) Int. Cl. H03M 1/12; H04N 5/44

(52) U.S. Cl. 348/839; 348/706; 348/725

(57) ABSTRACT

A modular digital television architecture and method of designing the same is disclosed. The television architecture includes a processing chassis module to convert an input signal into at a digital signal for use in providing information to a display. A presentation chassis module converts audio and visual components of the digital signal into a final signal for presentation on the display. An interface connects the processing and presentation chassis. The interface is a global interface capable of being used in conjunction with a plurality of chassis architectures. The processing and presentation chassis module are designed and operate independently of one another. The interface allows video, audio and digital data signals to be communicated over a single communication line. By employing a modular design, a variety of digital television systems can be readily produced.

This patent document is a Continuation in Part of U.S. patent application Ser. No. 09/862,391, filed May 21, 2001, for MODULAR DIGITAL TELEVISION ARCHITECTURE.

This patent document claims priority under 35 U.S.C. §119(e) to U.S. Provisional Patent Application Serial No. 60/335,575 filed Oct. 22, 2001 which is incorporated herein by reference.

### FIELD OF THE INVENTION

The present invention generally relates to digital televisions and, more particularly, to a system and corresponding method for providing a family of digital televisions based on a modular system architecture.

### BACKGROUND OF THE INVENTION

The design of conventional television systems requires the hardware components of the system to be completely designed before the software is developed for a given design. After the hardware design has been completed and certified, the software protocols implemented to perform the functionality of the particular system design are then developed. Thus, conventional television designs require a grouping of protocols to a specific hardware configuration.

Due to the one-to-one correspondence between the hardware and software, any change in the hardware design will result in the need to develop entirely new software protocols corresponding to the changed or otherwise revised, hardware design. Thus, interchanging or coupling a particular hardware design with a particular software protocol not originally developed for such hardware design is not possible. Consequently, the ability to upgrade or enhance the operational capabilities of a hardware design with new software is not possible.

Structurally, conventional television designs employ an architecture where audio and video signal processing and filtering operations are performed throughout the entirety of the system. Often times, the design of television systems are made more complex by the type and physical location of the components that perform the signal processing operations. Further adding to system complexity is the large amount of data that must be transferred between the processing elements. Due to the data transfer and signal processing constraints described above, conventional digital television designs generally require the use of two or more microcontrollers to carry out the necessary data transfer and signal processing operations. This results in the software used to control television system operation becoming increasingly complex and difficult to coordinate. The more complex the required software, the longer it takes to develop and debug the software. Consequently, the price of any resulting digital television system increases dramatically.

### SUMMARY OF THE INVENTION

The aforementioned and related drawbacks associated with conventional digital television system development have been substantially reduced or eliminated by the modular digital television architecture of the present invention.

In one embodiment, the invention can be characterized as a modular television, comprising a processing chassis having a power supply and circuitry configured to convert an analog audiovisual signal into at least one digital audiovisual signal and provide an intermediate digital signal derived from the at least one digital signal. The modular television also includes a presentation chassis having a display and circuitry configured to receive the intermediate digital signal, convert the intermediate digital signal into a display signal, and provide the display signal to the display. Additionally, an interface coupling the processing chassis and the presentation chassis is provided, the interface comprising a single communication line configured to carry the intermediate digital signal.

In another embodiment, the invention can be characterized as a method of making a modular television architecture, including the steps of: placing a processing chassis in a housing, wherein the processing chassis is configured to convert an analog signal into at least one digital signal and provide an intermediate digital signal derived from the at least one digital signal; placing a presentation chassis in a housing wherein the presentation chassis comprises a display and circuitry configured to receive the intermediate digital signal, convert the intermediate digital signal into a display signal, and provide the display signal to the display; and coupling the processing chassis and the presentation chassis with a single communication line.

In a further embodiment, the invention may be characterized as a modular television, including processing means for providing power to a power output and receiving an analog signal comprising audiovisual content, converting the analog signal into a digital audio signal and a digital video signal and providing an intermediate digital signal derived from the digital audio and digital video signals to a communication output. The modular television also includes presentation means for providing a display in response to the intermediate digital signal from the interface means. Additionally, the modular television includes interface means for receiving the intermediate digital signal from the communication output and the power from the power output and providing the intermediate digital signal and the power to the presentation means.

In yet another embodiment, the invention may be characterized as a digital television architecture, including a processing chassis configured to convert an analog input signal into at least one digital signal and to provide the at least one digital signal as an output, the processing chassis including a power supply. The digital television architecture also includes a presentation chassis configured to receive the at least one digital signal and to convert audio and video components of the digital signal into a final signal for presentation on a display, the presentation chassis being separate from the processing chassis and including a dedicated power source of the presentation chassis being different from the power source of the processing chassis. Additionally, the digital television architecture includes an interface configured to provide a communication path for the at least one digital signal between the processing chassis and the presentation chassis.

### BRIEF DESCRIPTION OF THE DRAWINGS

The aforementioned and related advantages and features of the present invention will become apparent upon review of the following detailed description of the invention, taken in conjunction with the following drawings, where like numerals represent like elements, in which:

FIG. 1 is a block diagram of an overall architecture of one embodiment of a digital television system of the present invention;

FIG. 2 is a block diagram of one embodiment of an interface architecture used to interconnect a processing chassis module and a presentation chassis module of the one embodiment of the digital television system of FIG. 1;

FIG. 3 is a schematic view of one embodiment of components that comprise a legacy block of the processing chassis module of FIG. 2;

FIG. 4 is a schematic block diagram of one embodiment of the components that comprise the processing chassis module of FIG. 2;

FIG. 5 is a schematic block diagram of one embodiment of the presentation chassis module of FIG. 2;

FIG. 6 is a block diagram of another embodiment of the interface architecture used to interconnect the processing chassis module and the presentation chassis module of the digital television system of FIG. 1;

FIG. 7 is a schematic block diagram of one embodiment of the components that comprise the processing chassis module of FIG. 6;

FIG. 8 is a schematic view of one embodiment of the components that comprise the legacy block of the processing chassis module of FIGS. 6 and 7;

FIG. 9 is a schematic block diagram of one embodiment of the presentation chassis module of FIG. 6; and

FIG. 10 is a schematic diagram of one embodiment of the digital television system of FIG. 1 in which the processing chassis module and the presentation chassis module are located within separate housings.

### DETAILED DESCRIPTION OF THE INVENTION

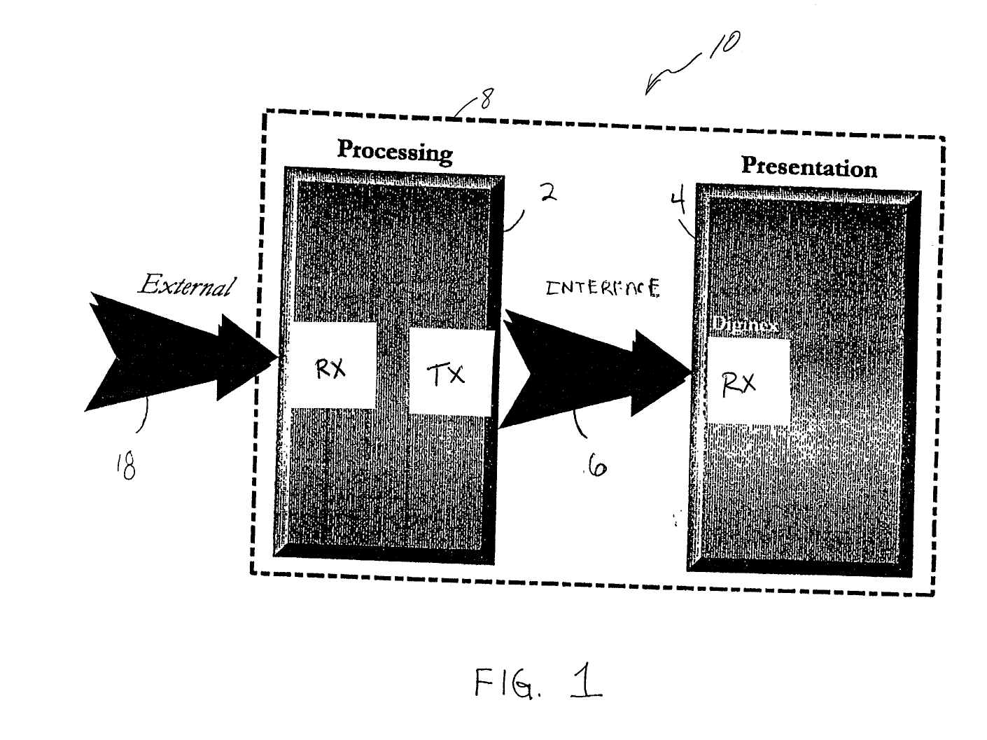

The modular digital television architecture and method of implementing the same will now be described with reference to FIGS. 1-10. FIG. 1 is a block diagram of the overall architecture of the digital television system of one embodiment of the present invention. As illustrated in FIG. 1, the digital television system (DTV) 10 includes a housing 8 enclosing a processing chassis module 2 (also generally referred to as a processing chassis 2), a presentation chassis module 4 (also generally referred to as a presentation chassis 4) and an interface 6 that is operative to interconnect and provide a communication path between the processing chassis module 2 and the presentation chassis module 4.

The processing chassis module 2 is operative to convert an analog input signal provided by an external source 18 (such as an antenna, a cable connection or a satellite feed) into at least a first digital signal before the audio and visual information contained within the first digital signal are presented to the user on a suitable display device (not shown). The display device can be a CRT or a suitable type of digital display device. In an exemplary embodiment, the display device is implemented as a CRT. The signals generated by the processing chassis module 2 are transmitted through the interface 6 to the presentation chassis module 4. The corresponding CRT (or other display device) operates under the control of the presentation chassis module 4.

The presentation chassis module 4 includes all of the necessary components used to filter the incoming digital signals and to display the video images contained within the digital signals, and receive and play audio recordings. The audio and video information presented to the user by the presentation chassis module 4 are provided thereto by the interface 6.

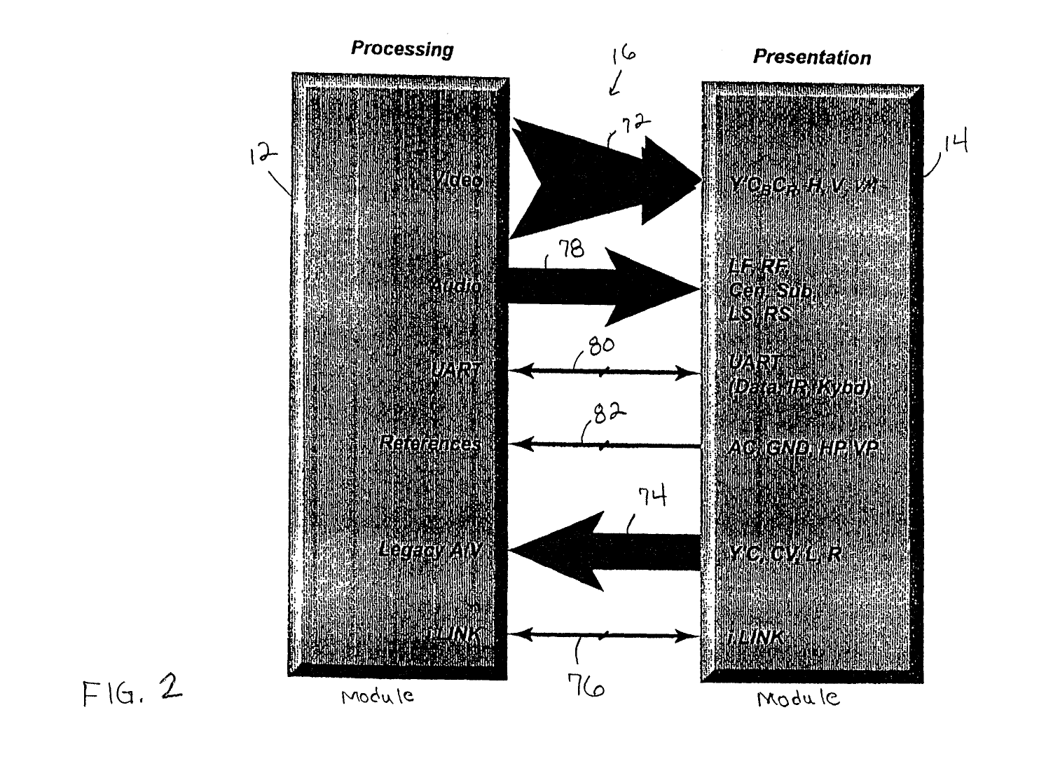

Referring next to FIG. 2, shown is a block diagram of one embodiment of the interface architecture used to interconnect the processing chassis module 12 and the presenting chassis module 14. The interface 16 is a global interface that can be used in conjunction with several different types of chassis modules and architectures. In application, the interface 16 is comprised of a series of transmission lines that provide a communication path between the processing chassis module 12 and the presentation chassis module 14. As shown in FIG. 2, the interface 16 includes video signal transmission lines 72 that transfer digital video information signals from the main processing block 40 of the processing chassis module 12 to the presentation chassis module 14. Audio line 78 provides the audio information (i.e. left audio, right audio, etc.) to the presentation chassis module 14. Bi-directional UART line 80 transfers basic communication information, received infrared commands and push button commands from the front panel of the display in addition to the corresponding reference signals between the two chassis modules. Reference line 82 transmits power, ground and additional timing information from the presentation chassis module 14 to the processing chassis module 12. Legacy signal line 74 and bi-directional i.LINK line 76 transfer the front panel information between the presentation chassis module 14 and the processing chassis module 12.

According to the present invention, the video signal transmission lines 72 use transition minimized differential signaling (TMDS) for the base electrical interconnection between the processing chassis module 12 and the presentation chassis module 14. The transition minimization can be achieved, for example, by implementing an advanced encoding algorithm that converts 8-bits of data into a 10-bit transition minimized, dc balanced character. According to an exemplary embodiment, the video signal transmission lines 72 of the present invention are a part of a physical structure including a transmitter (not shown) which incorporates an advanced coding algorithm to enable TMDS signaling which reduces the electromagnetic interference across the aforementioned transmission lines.

In an exemplary embodiment of the present invention, the video signal transmission lines 72 of the interface 16 operate according to the Digital Visual Interface (DVI) 1.0 specification promulgated by the Digital Display Working Group (DDWG), which is incorporated fully herein. As such, the interface 16 can be used in conjunction with a variety of chassis (i.e. digital component) modules to provide a high speed digital connection for visual data types that is display technology independent. In an alternate embodiment, the video signal transmission lines 72 operate according to the EIA 861 standard promulgated by the Consumer Electronics Association (CEA).

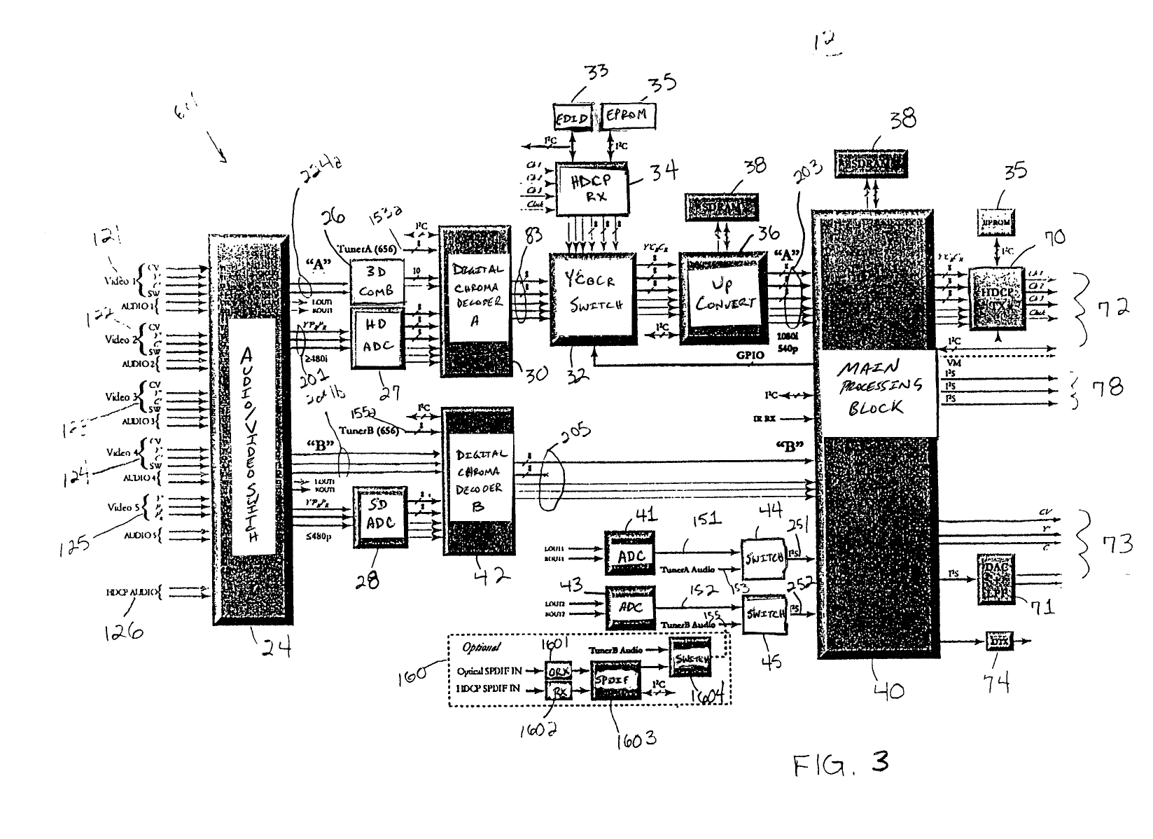

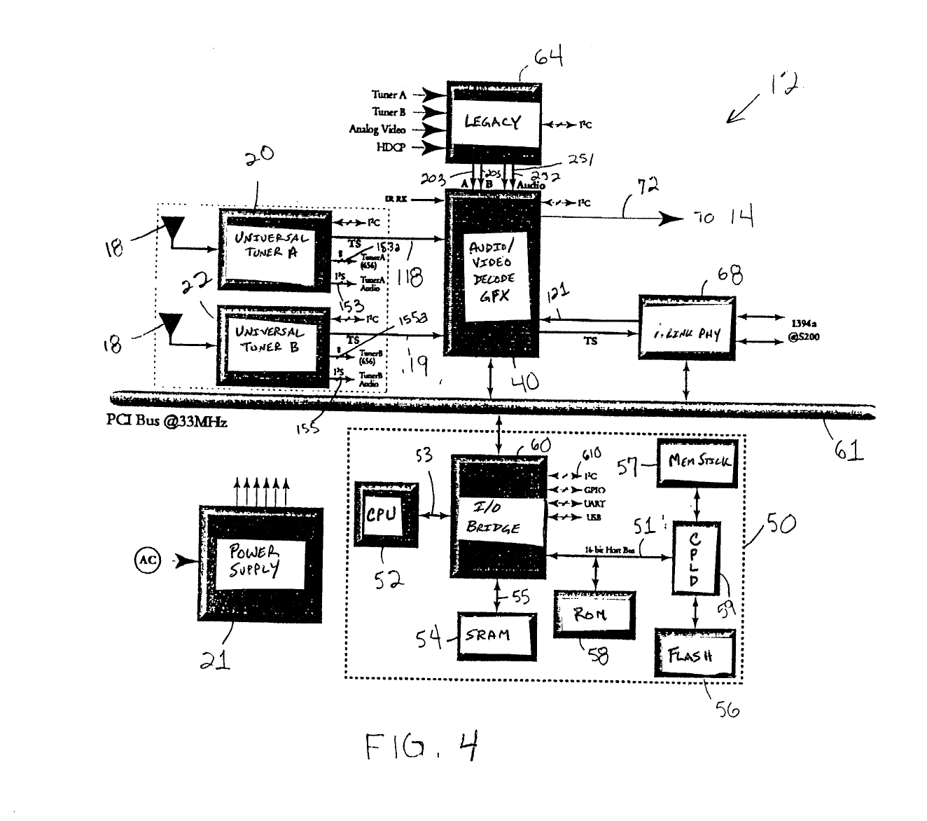

The processing chassis module 12 of FIG. 2 will now be described with reference to FIGS. 3 and 4. The processing chassis module 12 is responsible for converting the analog input signal(s) received by the external source 18 (FIG. 1) into at least a first digital signal which includes both the audio and video information contained in the input signal(s). Initially, the analog input signal(s) are digitized and up converted to an appropriate digital format by a legacy block 64 (FIG. 4). The digital signals are then transmitted to and processed by the main processing block 40 of the processing chassis module 12. For purpose of description and identification, the components to the left of the main processing block 40 comprise the legacy block 64. In an exemplary embodiment of the present invention, the audio and video information is provided to the main processing block 40 on two channels, referred to as channel A (“A”) and channel B (“B”), respectively. The particular channel that the audio and video information is provided on is determined by audio/visual (A/V) switch 24.

Referring to FIG. 3, the video processing section of the processing chassis module 12 will now be described. As shown, the input analog audio and video signals (121-126) are provided as inputs to the A/V switch 24. The A/V switch 24 controls whether the resulting output signals are provided on channel A or channel B or both. For example, FIG. 3 illustrates the information present on Video line 1 121 being provided on channel A while the video information present on Video line 4 is provided on channel B. For purposes of clarity, channel A processing will be described first; then channel B processing will be described.

The input signals 121-125 of the A/V switch 24 are received by the external source 18 (FIG. 1) and comprise composite video signals. The information present on line 126 is comprised of high definition audio signals. More specifically, the video information 121-125 is embodied in four types of signals: (1) standard composite video signals (CV); (2) S-video information, such as provided by DVD media (Y and C); and (3) S-video identification information (SW). Each of these signals are provided as inputs to the A/V switch 24, which provides a corresponding subset of the signals on channel A (lines 224a). The determination of which signals are provided on a given channel is determined, in part, on the identification information present on line SW. The audio information present, for example, on line 121 is provided by the A/V switch 24 on audio lines LOUT1 and ROUT1.

Video line 5 125 is comprised of component video signal information. Depending on the state of the A/V switch 24, the component video signals are transmitted to a high definition analog-to-digital converter (ADC) 27 on line 201.

Referring back to the composite video signals (CV, Y and C), these signals are transmitted to a 3D Comb filter 26 from the A/V switch 24. The 3D Comb filter 26 operates to separate the luminance (brightness) and chrominance (color) information from the input signals. The resulting brightness and color information, along with command information present on line I²C and video type (ITU BT.656 or digital CVBS (also known as digital composite video)) information from front end tuner module 20 (FIG. 4) on line 656, is transmitted to a first chroma decoder 30.

The first chroma decoder 30 decodes the corresponding brightness, color and video information from the video signals input thereto. Such decoding includes the detection of closed captioning, wide screen, V-chip and other video presentation information transmitted by the input signals. The output of the first chroma decoder 30 is either a standard resolution (480i) NTSC signal or a higher resolution (≧480p) NTSC signal.

After the input video signals have been decoded and digitized by the first chroma decoder 30, the resulting digital video signals are then transmitted on line 83 as inputs to a component video (Y′C_{B}C_{R}) switch 32. Additional inputs to the component video switch 32 are provided by a DVI receiver 34 which, according to several embodiments, is a DVI receiver with High Bandwidth Digital Content Protection (HDCP). Inputs to the DVI receiver 34 include system command information on line I²C, video channel information on lines Ch1-Ch3 and system clock (Clock) information. The command information is comprised of, for example, monitor identification type information maintained in the Extended Data Identification Module (EDID) 33 and any encryption keys. The encryption keys are stored in EPROM memory 35. The output of the DVI receiver 34 can be comprised of either high definition or standard definition component video signals. Accordingly, a first subset of inputs to the component video switch 32 consists of digitized component video signals. A second subset of inputs consists of digital component video signals from the DVI receiver 34. Based on the inputs provided thereto, the component video switch 32 will transmit either the digitized component video signals or digital component video signals to an up converter 36 for further processing.

The up converter 36 converts the video signals provided by the component video switch 32 into corresponding output signals as illustrated in Table 1 below.

TABLE 1

| Input Signal | Output Signal |
|---|---|
| 480 i | 540 p or 1080 i |
| 480 p | 540 p |
| 720 p | 540 p or 1080 i |
| 1080 i | 1080 i |

As shown in Table 1, a 480i input signal will be converted into a 1080i signal; a 480p input signal will be converted into a 540p signal; and a 720p input signal will be converted into either a 540p or a 1080i signal. A 1080i input signal will pass unchanged through the up converter 36. In application, the 480p video signal is a higher resolution signal as compared to a standard 480i signal.

The up converter 36 includes a corresponding memory (SDRAM 38) which stores the digitized information, referred to as digital reality creation signals, of the up converter 36. After being converted, the video signals are then transmitted to the main processing block 40 on line 203. The processing of the signals transmitted to the main processing block 40 will be described in greater detail below with reference to FIG. 4.

The video signals provided on channel B will now be described. The processing chassis module 12 employs a second chroma decoder 42, similar in structure and operation to first chroma decoder 30, to decode and digitize the corresponding input video signals (i.e., Video 1 121, Video 2 122, Video 3 123, Video 4 124 and Video 5 125) provided on channel B by the A/V switch 24. In an exemplary embodiment, the video signals transmitted on channel B are only 480i and 480p signals. Thus, after the input video signals have been decoded and converted into digital format by the second chroma decoder 42, they are transmitted directly into the main processing block 40 on line 205 for further processing. In operation, the second chroma decoder 42 is used to digitize the second picture of a twin picture function. As used herein, the twin picture is defined to mean adjacent picture information which may be present on video input lines 121-125.

Additionally, the video signals provided by the A/V switch 24 on channel B are standard definition (≦480p) signals. These standard definition signals are converted into digital signals by the standard definition ADC 28 before being transmitted to the second chroma decoder 42 for processing.

The audio processing section of the processing chassis module 12 will now be described. As illustrated in FIG. 2, audio signals from the various front panel channels (1121-125) are provided to the A/V switch 24 on corresponding audio lines (Audio 1-Audio 5). High definition audio signals are transmitted to the processing chassis module 12 from the external source 18 (FIG. 1) on line 126. The analog audio signal information is provided by the A/V switch 24 on corresponding lines LOUT1-LOUT2 and ROUT1-ROUT2.

Audio signals LOUT1 and ROUT1 are provided as inputs to an ADC 41. The digital output signal provided by the ADC 41 on line 151 is provided as the first input to a first audio switch 44. The second input to the first audio switch 44 is provided by a direct tuner audio on line 153. The output of the first audio switch 44 is then transmitted to the main processing block 40 on line 251 for further processing.

Audio signals LOUT2 and ROUT2 are provided as inputs to an ADC 43. The digital output signal provided by the ADC 43 on line 152 is provided as the first input to a second audio switch 45. The second input to the second audio switch 45 is provided by direct tuner audio on line 155. The output of the second audio switch 45 is transmitted to the main processing block 40 on line 252 for further processing.

In an alternate embodiment, the second input to the second audio switch 45 is provided by the output of a digital audio module 160. The digital audio module 160 is comprised of a plurality of input receivers 1601 and 1602. The input of first input receiver 1601 is provided by an optical analog input (SPDIF IN). The input to the second input receiver 1602 is provided by a secondary digital audio input signal (HDCP SPDIF IN). The corresponding outputs of the receivers 1601 and 1602 are provided as inputs to a receiver 1603. A third input to the receiver 1603 is provided by a control signal on line I²C. The output of the receiver 1603 is provided as a first input to switch 1604. The other input to switch 1604 is provided by tuner A or B audio. In the alternate embodiment, the output of the switch 1604 replaces the direct audio from tuner B on line 155. In a second alternate embodiment, the output of the switch 1604 replaces the direct audio from tuner A on line 153.

After a suitable level of processing has been performed on the audio input signals present on lines 251-252, the processed audio data is provided by the main processing block on line 78. Other output signals provided by the main processing block 40 include monitor output line 73. The output signals present on line 73 are down converted to 480i format and then transmitted to a video cassette recorder (VCR), or other suitable device, for later playing or recording.

The processed digital video signal information, whether on channel A or channel B, are transmitted to a high definition transmitter 70. Other data transmitted to the transmitter 70 include signals from the (optional) front-end tuners 20, 22 on lines 118 and 119, respectively (FIG. 4) and data from the i.LINK module 68 on line 121 (FIG. 4). The transmitter 70 then encrypts the digital video data, if necessary, based on encryption key data present in memory unit (EPROM) 35. The digital video data is then provided on corresponding channel lines Ch1-Ch3. The digital video signals, which may be referred to as intermediate digital signals, on lines Ch1-Ch3, the command control line I²C and the information present on analog signal line VM are all transmitted to the presentation chassis module 14 on line 72 via the interface 16.

FIG. 4 is a schematic block diagram of the components that comprise the processing chassis module of the present embodiment. The processing chassis module 12 includes a processor section 50 including a central processing unit (CPU) 52, an SDRAM 54, a flash memory 56, a read only memory (ROM 58) and an I/O Bridge 60. An optional memory stick interface 57 and CMOS programmable logic device (CPLD) 59 are also shown. The ROM 58 is connected to the I/O Bridge 60 through a processor bus 51. The flash memory 56 of the processor section 50 is also coupled to the processor bus 51 via CPLD 59. The SDRAM 54 is connected to the I/O Bridge 60 via a dedicated bi-directional line 55. Other inputs to the I/O Bridge 60 include information contained on a I²C line 610 which is used to transfer basic communication signals, a USB connection, general purpose I/O lines (GPIO) as well as an UART line 80 (FIG. 4) which is used to transfer control information between the chassis modules. The CPU 52 executes the protocols stored in either the flash memory 56 or the ROM 58. The CPU 52 acts as an overall system (digital television) controller.

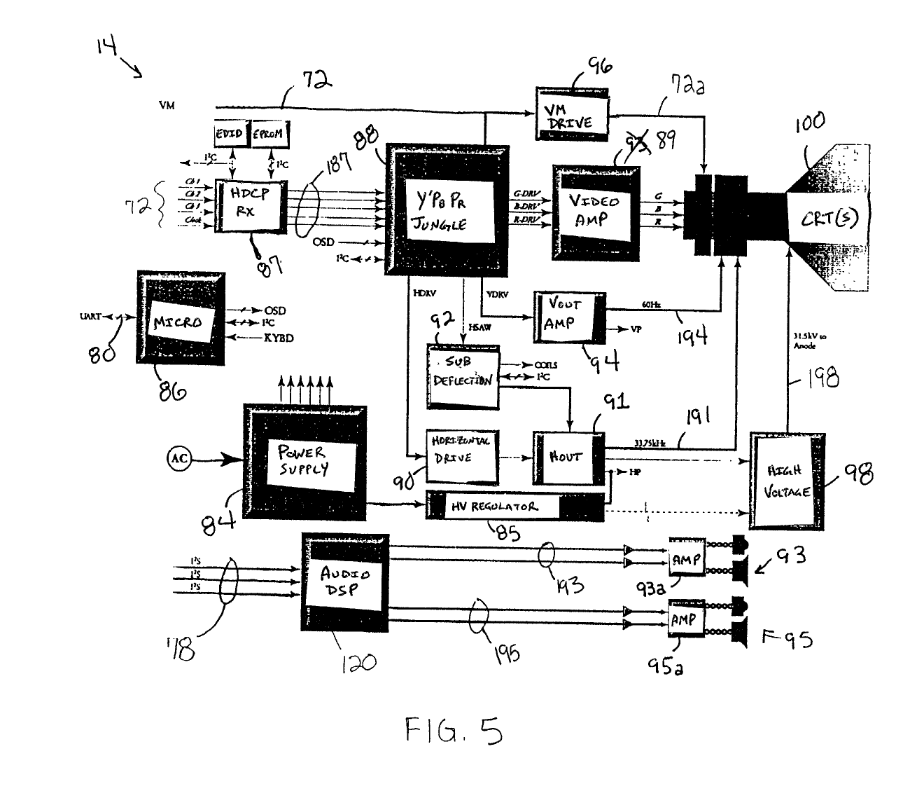

The main processing block 40, in an exemplary embodiment, is also an MPEG module that generates the video images that are presented on the display 100 (FIG. 5) based on the signals input thereto according to the specifications promulgated, for example, by the Motion Picture Expert Group. The output of MPEG module 40 is provided to the presentation chassis module 14 via line 72. Other inputs to the MPEG module 40 include a signal from a front end ATSC tuner module 20 operating in accordance with the specification promulgated by the Advanced Television Systems Committee (ATSC). The ATSC tuner module 20 transmits an ATSC signal into the main processing block 40 on line 118. Another input to the MPEG module 40 is provided by an optional front end DirecTV™ and Smart Card module 22, which transmits a satellite signal into the main processing line 40 on line 119. The DirecTV™ and Smart Card module 22 is also connected to the MPEG module 40 via bi-directional line 120. Also shown in FIG. 4 is an i.LINK signal on line 121 being provided as an input into the MPEG module 40 of the main processing block 40. The i.LINK signal is generated by an i.LINK element 68. The i.LINK element 68 transmits a signal from the front panel of the digital television system 10 to the i.LINK module located within the processing chassis module 12.

Power for both the video processing section and the audio processing section of the processing chassis module 12, as well as the main processing block 40, is provided by a dedicated low voltage power supply 21. In operation, the low voltage power supply 21 generates substantially about 5W of power.

One of the objectives of the processing chassis module 12, is to transmit all of the audio and video information provided by the respective tuners and decoders into the main processing block 40 as quickly as possible, while at the same time minimizing the number of domain changes that need to be performed on the input signals. For purposes of the present invention, domain changes refer to the number of times a signal has to be converted from analog-to-digital or digital-to-analog. As illustrated in FIG. 3, such domain changes are minimized by having the input audio and video signals being converted from one domain (analog) to another domain (digital) only once by the high definition ADC 27 and/or the corresponding standard definition ADC 28.

In operation, the analog audio and video signal information are received by the external source 18 (FIG. 1) and are transmitted into the processing chassis module 12 via the A/V switch 24. The A/V switch 24 then transmits corresponding audio and video information on either a first channel (Channel A) or a second channel (Channel B). In an exemplary embodiment, video data ≧480i is transmitted on Channel A. Standard definition video data (≦480p format) is transmitted on Channel B. The brightness and color information contained within the video signals is separated by the 3D Comb 26 and then decoded and digitized by the first chroma decoder 30. The video information on Channel A is then converted into a digital signal, for processing, by the ADC 27. The video information is then transmitted to a component video switch 32, which provides either the standard definition video signal or a corresponding high definition video signal to an up converter 36.

If the signal provided by the component switch 32 is a standard definition video signal, such signal is converted into a higher definition (540p or 1080i format) video signal by the up converter 36. The resulting video signal is then transmitted to the main processing block for processing. If the signal provided by the component switch 32 is a high definition video signal, such signal passes directly through the up converter 36 to the main processing block 40 without being changed. An exception to the direct passage scheme described above occurs when the signal provided by the component video switch 32 is a 720p format signal (see Table 1). In such a situation, the 720p format signal is converted to either a 540p or a 1080i signal.

In corresponding fashion, video signals present on Channel B which are already in standard definition (≦480p) format, are digitized by the second chroma decoder 42 and transmitted directly to the main processing block 40 for processing. The audio signals received by the external source 18 (FIG. 1) are transmitted to the main processing block 40 for processing after first being converted into digital format by associated ADC's 41 and 43, respectively. The processed audio signals are then provided to corresponding audio delivery components (e.g. speakers) which are capable of delivering sounds to a user.

Upon being received in the main processing block 40, the digital video input signals are representative of the video images that are presented on the display device based on a particular protocol. The output of the main processing block 40 is then transmitted to the interface 16 on transmission line 72. As illustrated in greater detail in FIG. 3, the video transmission line 72 is comprised of the digital video data present on Ch1-Ch3, the system clock (Clock), line VM and the control signal I²C.

Referring next to FIG. 5, shown is a schematic block diagram of one embodiment of the presentation chassis module of FIG. 2. The presentation chassis module 14 includes a display 100 and at least a pair of speaker units 93 and 95, respectively, operative to present video and audio information to a user. In an exemplary embodiment, the display 100 is a CRT display that is operative to present the video information based on the signals generated by the processing chassis module 12 and transferred through the interface 16. In addition to being a CRT display, the display 100 can be any of the digital display devices presently available on the market. The display 100 includes a front panel (not shown) having a plurality of buttons that are used to adjust the characteristics of the video and audio information presented to the user. The presentation chassis module 14 further includes a processor 86, which transmits and receives signals from the UART line 80. The microprocessor 86 is used to process and transmit information, for example, from the front panel of the display 100 to the processing chassis module 12.

A DVI receiver 87, which according to several embodiments is a DVI receiver with HDCP encryption, includes a digital-to-analog converter (DAC) that converts the input digital video signals on lines Ch1-Ch3 (which collectively may be referred to as an intermediate digital signal) received from the main processing block 40 into analog signals, which may be referred to as display signals, on lines 187. The analog signals are transmitted to display capture hardware 88 for further processing. Display capture hardware 88, provides for the proper timing of the received signals for presentation on the display device 100. In operation, the display capture hardware 88 receives the analog signals on lines 187 from the DVI receiver 87 and synchronizes the analog signals, and then performs optional final color matrix conversion, brightness, hue and contrast processing operations on the received signals. It should be noted that the aforementioned brightness, hue and contrast processing operations could also be performed in the processing chassis module 12. A first subset of the processed signals are transmitted to the horizontal timing circuitry (HOUT) 91 via the horizontal controller circuitry 90 for presentation of properly adjusted horizontal component video signals to the display device 100. A second subset of the processed signals are transmitted to the vertical timing and amplifier circuitry (VOUT) 94 for presentation of properly adjusted vertical component video signals to the display device 100. A third subset of processed signals is transmitted to sub-deflection circuitry 92 for additional processing before being provided as an input to the horizontal output circuitry 91.

After being processed in the display capture hardware 88, the remaining signals are amplified by the video amplifying circuitry 89 before being presented to and displayed on the display device 100. The output of the video amplifier 89 are the Green (G), Blue (B) and Red (R) pixel signals that form the image displayed on the display device 100. The vertical (VOUT) and horizontal (HOUT) control signals corresponding to the resulting image are provided by the VOUT 94 and HOUT 91 circuitry on lines 194 and 191, respectively. As further illustrated in FIG. 4, the velocity module (VM) video signal is transmitted directly from the processing chassis module 12 into the VM drive 96. The output of the VM drive 96 is transmitted to the control section of display device 100 for incorporation into the composite signal that is displayed to the user. The audio signals transmitted from the processing chassis module 12 on lines 78 are processed by the audio digital signal processing (DSP) chip 120 and then provided to the speaker units 93, 95 for presentation to the user. For example, the audio to be provided by speaker unit 93 is transmitted thereto on line(s) 193. The audio to be provided by speaker unit 95 is transmitted thereto on line(s) 195.

The presentation chassis module 14 also includes a dedicated high voltage power supply 84 that provides power to the components maintained within the module. For example, power is transmitted from the power supply 84 to the display device 100 through a pair of high voltage regulation components 85 and 98, respectively. In an exemplary embodiment, the power supply 84 provides between 5W-1kW of power to the components of the presentation chassis module 14. It is important to note that the power supply 84 of the presentation chassis module 14 is separate from and operates independently of the low voltage power supply 21 used in the processing chassis module 12. In this embodiment, the power supply 84 of the presentation chassis module 14 needs to be separate from the low voltage power supply 21 of the processing chassis module 12 because the presentation chassis module 14 never knows what type of processing chassis module it is interfacing with. Thus, by providing for independence of operation, the processing and presentation chassis modules of the present invention can be interconnected in any suitable combination.

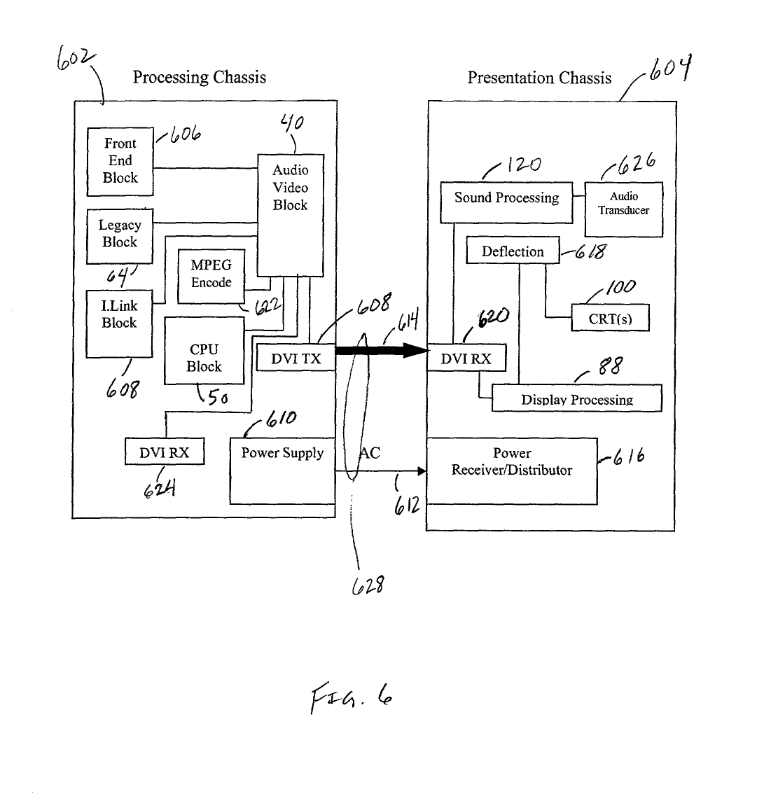

Referring next to FIG. 6, shown is a block diagram of another embodiment of an interface architecture used for the digital television system of FIG. 1. Shown is a processing chassis module 602 (also generally referred to as a processing chassis 602) having a front end block 606 (comprising the external source 18 and front end tuners 20, 22), the legacy block 64, an i.LINK module 608, the main processing block 40, the processor section 50, a Digital Visual Interface (DVI) transmitter module 608, a Motion Picture Experts Group (MPEG) encoder module 622 and a digital content receiver 624.

Also shown is a presentation chassis module 604 (also generally referred to as a presentation chassis 604) having the display 100, the audio digital signal processing (DSP) chip 120, a presentation power supply 616, a deflection module 618 (comprising the sub-deflection circuitry 92, amplifier circuitry (VOUT) 94, the horizontal output circuitry 91, the horizontal controller circuitry 90, and the high voltage regulation components 85 and 98), the display capture hardware 88, a Digital Visual Interface (DVI) receiver module 620, and an audio transducer module 626 (comprising the at least the pair of speaker units 93 and 95). Additionally, a multi-signal communication line 614 and a power line 612 are shown.

Within the processing chassis module 602, the main processing block 40 is coupled to the front end block 606, the MPEG encoder module 622, the Digital Visual Interface (DVI) transmitter module 608, the processor section 50, the legacy block 64, the i.LINK module 608, and the digital content receiver 624. The processing chassis module 602 is connected to the presentation chassis module 604 via the multi-signal communication line 614, which couples the Digital Visual Interface (DVI) transmitter module 608 and the Digital Visual Interface (DVI) receiver module 620. Additionally, the power line 612 connects the processing power supply 610 with the presentation power supply 616.

Within the presentation chassis module 604 the Digital Visual Interface (DVI) receiver module 620 is coupled to the audio digital signal processing (DSP) chip 120 and the display capture hardware 88. The audio digital signal processing (DSP) chip 120 is coupled to the audio transducer module 626. The deflection module 618 is coupled to the display capture hardware 88 and the display 100.

In this embodiment, the interface 628 between the processing chassis module 602 and the presentation chassis module 604 is simplified so that the video signal transmission line 72, the audio line 78, and the UART bus 80 are replaced with a single communication line, i.e. the multi-signal communication line 614. Advantageously, the simplification of the interface 628 from the embodiment illustrated in FIG. 2 (that has separate video, audio and data signal lines) to the present embodiment (that has the multi-signal communication line 614) makes software development easier and more reliable; thus, reducing development costs. Additionally, the multi-signal communication line 614 in this embodiment may be implemented with industry standard cables and connectors that conform to standards set by, for example, the Digital Display Working Group (DDWG). Because a single industry standard cable may be used in the present embodiment, it is easier for an assembler or the end user to physically couple the processing chassis module 602 and the presentation chassis module 604 than coupling processing and presentation chassis modules in the embodiments described with reference to FIG. 2.

In operation, the embodiment illustrated in FIG. 6 operates in much the same way as the embodiment illustrated in FIG. 2. In this embodiment, however, the Digital Visual Interface (DVI) transmitter module 608 multiplexes digital audio signals from the audio line 78, digital video signals from the video signal transmission line 72, and digital data signals (also referred to as “info packets”) over the multi-signal communication line 614. The digital data signals convey system information, for example, display capabilities, active video information, and user definable functions. Thus, as opposed to the embodiments described with reference to FIG. 2 where system information is provided to the presentation chassis module 14 via the UART bus 80, in the present embodiment, a signal of multiplexed audio, video, and digital data signals, which is referred to herein as an intermediate digital signal, is provided over a single communication line, i.e., the multi-signal communication line 614.

In several embodiments, the multiplexing of digital audio, digital video and digital data conforms to EIA standard 861B. Alternatively, the multiplexing of digital audio, digital video and digital data conforms to multiplexing standards established by the Digital Display Working Group, for example, DVI-CE specifications. In yet other embodiments, the multiplexing of digital audio, digital video and digital data conforms to DMI standards. It is important to note, however, that the present invention is not dependent upon a particular multiplexing scheme and may be implemented with various other multiplexing schemes.

The multiplexed audio, video and digital data signal, which is referred to as an intermediate signal or intermediate digital signal, is then carried by the multi-signal communication line 614 to the Digital Visual Interface (DVI) receiver module 620 where the multiplexed audio, video and digital data signals are de-multiplexed and the audio and video signals are converted from digital into analog signals. The audio signal is then relayed to the digital signal processing (DSP) chip 120 and the video signal is relayed to the display capture hardware 88 where, as discussed with reference to FIG. 5, the audio and video signals are processed for presentation to the viewer. The hardware used to implement the DVI transmitter module 608 and the (DVI) receiver module 620 may be obtained from suppliers including Intel Corporation of Santa Clara, Calif. and Silicon Image Inc. of Sunnyvale, Calif.

Thus, in the present embodiment, the multi-signal communication line 614 comprises a single path for digital audio, digital video and digital data signals that are combined to form a single complex signal, i.e., the intermediate digital signal. As such, the multi-signal communication line 614 is a single communication line for the intermediate digital signal. It should be recognized, however, that even though the multi-signal communication line 614 is referred to as a single communication line, it may comprise two or more electrically isolated conductors. In what ever physical form the multi-signal communication line 614 embodies, the conductors together form a single communication line or one path, and digital audio, digital video, and digital data signals (combined as a single complex signal) propagate together over the one path.

In several embodiments, the video and audio signals are encrypted by the Digital Visual Interface (DVI) transmitter module 608 before being transmitted to the processing chassis module 604 to prevent unauthorized access to the content of the digital audio and video signals. This encryption may be in accordance with, for example, the High-bandwidth Digital Content Protection (HDCP) specification. Thus, in several embodiments, the intermediate digital signal comprises encrypted and multiplexed digital audio and digital video signals along with digital data signals. In such embodiments, the encrypted and multiplexed digital video and audio signals are de-multiplexed and decrypted by the Digital Visual Interface (DVI) receiver module 620 before being processed for presentation.

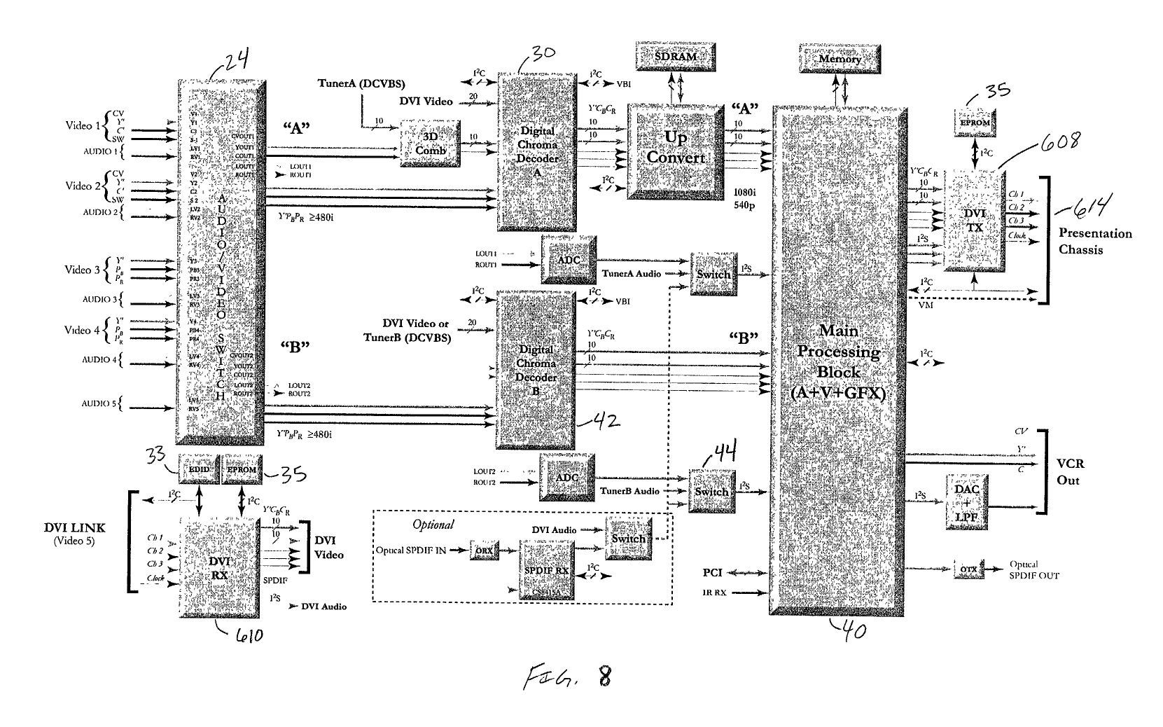

In several embodiments, encryption keys as well as information about the processing chassis module 602 and the type of data being transmitted from the processing chassis module 602 is stored in an EPROM memory 35 (shown in FIG. 8). Thus, according to several embodiments, the processing chassis module 602 is able to communicate the type of multiplexing scheme it utilizes (to combine the digital audio, video and data signals) to the presentation chassis module 604. As a result, different types of presentation chassis modules are able to receive and respond to the processing chassis module 602 and accept and process the digital audio, video and data signals from the processing chassis module 602.

The processing power supply 610 in this embodiment provides operable power to both the processing chassis module 602 and the presentation chassis module 604. Having the processing chassis module 602 provide power to the presentation chassis module 604 enables more sophisticated power moding procedures to improve energy conservation. In several embodiments, for example, the processing chassis 602 controls the opening and closing of a relay that switches power to the presentation chassis 604. Those skilled in the art recognize that other power moding schemes may be implemented to manage power in an efficient manner.

The presentation power supply 616 in this embodiment receives power, e.g., 110-120 VAC at 50-60 Hz, from the processing power supply 610 via the power line 612. The presentation power supply 616 functions to both distribute power received from the processing chassis module 602 to all the electrical components within the presentation chassis module 604 and to provide the appropriate power levels to each of the electrical components within the presentation chassis module 604.

In the present embodiment, analog audio and video (i.e, legacy AV) and digital audio and video connections for the user are located within the processing chassis module 602 as opposed to the presentation chassis module 604. Having legacy AV available for the user at the processing chassis module 602 eliminates the need for the legacy signal line 74 (illustrated in FIG. 2) because the user in the present embodiment may access legacy AV at the processing chassis module 602 instead of the presentation chassis module 604 (where the user accesses legacy AV signals in the embodiment illustrated in FIG. 2). The addition of the MPEG encoder module 622 in the processing chassis module enables legacy signals to be encoded and provided digitally to external devices via the i.LINK module 68; thus providing networking connectivity from the processing chassis module 602. As a result, the legacy signal line 74 of the embodiment illustrated in FIG. 2 is no longer necessary because the user in the present embodiment is able to access digital audio visual signals from an i.LINK connection at the processing chassis module 602 instead of the presentation chassis module 602 (where the user accesses the i.LINK connection in the embodiment illustrated in FIG. 2).

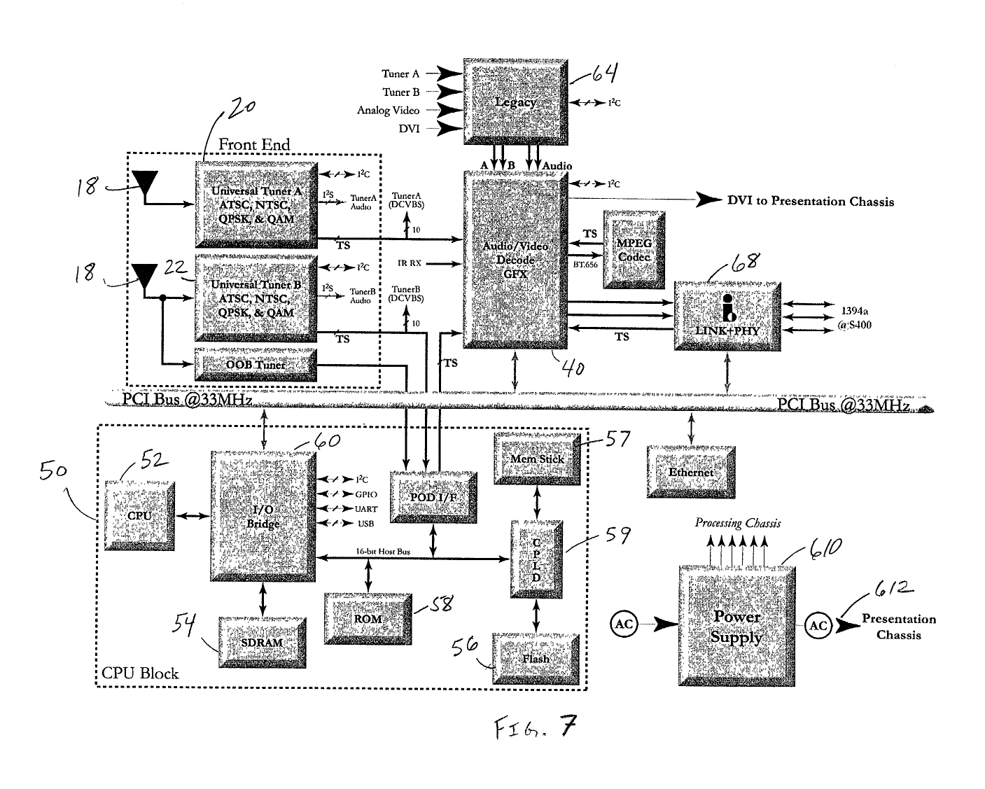

Referring next to FIGS. 7 and 8, shown are schematic views of one embodiment of the components that comprise the processing chassis module 602. Shown in FIG. 7 are components that comprise the processing chassis module 602 of the embodiment illustrated in FIG. 6. In practice, the components shown in FIG. 7 interoperate similarly to those described with reference to FIG. 4 except that, the processing power supply 610 of FIG. 7 has a power output that provides power over the power line 612 to the presentation chassis module 604.

In operation, the embodiment of FIG. 8 operates in much the same way as the embodiment illustrated in FIG. 3 except that functional features of the component video switch 32 are undertaken by the first chroma decoder 30 and the second chroma decoder 42. In this embodiment, the system command information on line I²C, video channel information on lines Ch1-Ch3 and system clock (Clock) information that are described as being received by the DVI receiver 34 (in the embodiment illustrated in FIG. 3) are received instead at the digital content receiver 624. The digital content receiver 624 operates in a similar manner to the DVI receiver 34 except that the digital component video signals output from the first chroma decoder 30 are provided directly to the main processing block 40 instead of being switched through the component video switch 32.

An additional difference between the present embodiment and the embodiment illustrated in FIG. 2 (discussed in detail with reference to FIGS. 3-5) is that the transmitter 70 shown in FIG. 3 is replaced with the Digital Visual Interface (DVI) transmitter module 608. The Digital Visual Interface (DVI) transmitter module 608 in the present embodiment multiplexes audio, video and digital data signals over the multi-signal communication line 614; thus, eliminating the separate video signal transmission line 72, separate audio line 78 and separate UART line 80 shown in FIGS. 2 and 3.

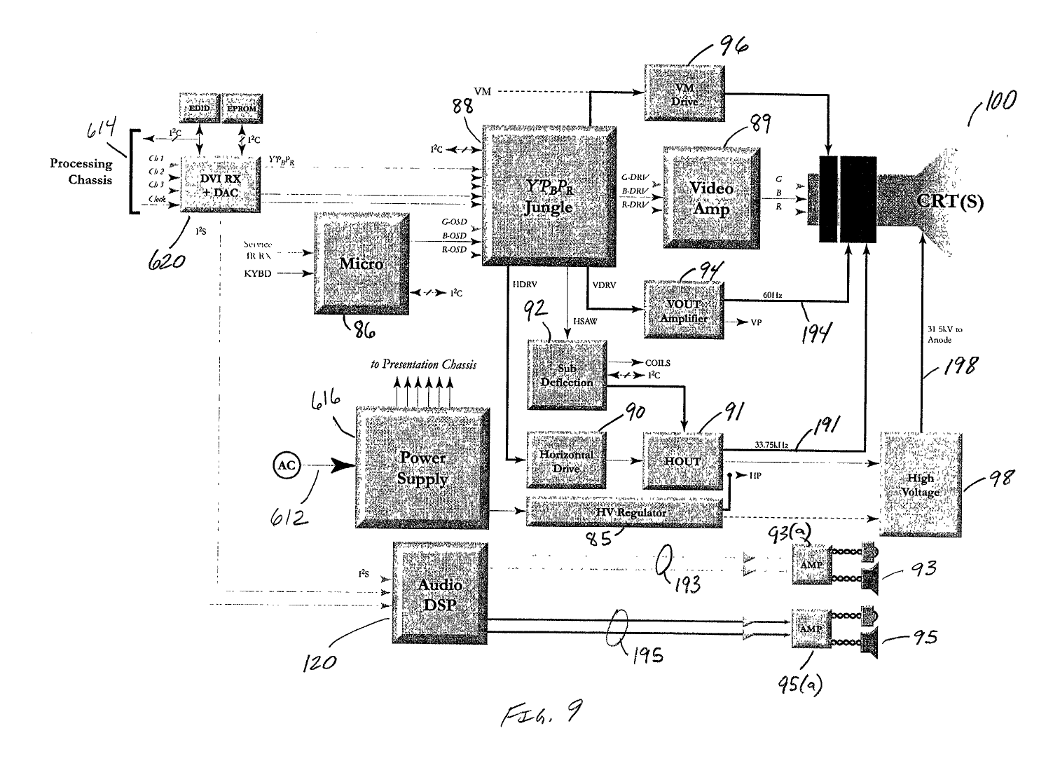

Referring next to FIG. 9, shown is a schematic block diagram of one embodiment of the presentation chassis module 604 of FIG. 6. The components shown in FIG. 9 interoperate in a similar manner as those described with reference to FIG. 5. One exception, however, is that multiplexed video, audio and digital data signals are provided to the Digital Visual Interface (DVI) receiver module 620 via the multi-signal communication line 614. These signals are de-multiplexed by the Digital Visual Interface (DVI) receiver module 620 and relayed to other components of the presentation chassis module 604 instead of being provided to the presentation chassis module 604 via the video line 72, the audio line 78 and the UART bus 80 as shown in FIG. 5.

Another difference between embodiments described with reference to FIG. 5 and embodiments described with reference to FIG. 9 is the power supply 84 (described with reference to FIG. 5) is replaced with the presentation power supply 616. As discussed with reference to FIG. 6, the presentation power supply 616 is supplied with power from the processing power supply 610 of the processing chassis module 602. After receiving power from the processing power supply 610, the presentation power supply 616 distributes the received power to components of the presentation chassis module 604. Thus, in the present embodiment, the presentation power supply 616 is dependent upon the processing power supply 610 for power. It should be recognized, however, that the presentation power supply 616 in other embodiments receives power from other sources, e.g., an ordinary household electrical outlet.

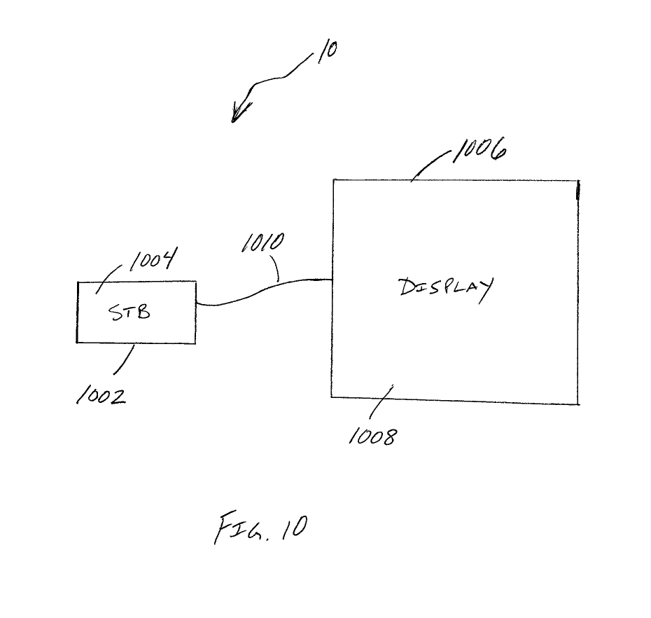

Referring next to FIG. 10, shown is a schematic diagram of another embodiment of the digital television system 10 of FIG. 1 in which the processing chassis module 12, 602 and the presentation chassis module 14, 602 are located within separate housings. Shown is the digital television system 10 in which the processing chassis module 12, 602 is within a set-top box 1004 and the presentation chassis module 14, 602 is within a display unit 1008. Coupling the set-top box 1004 and the display unit 1008 is a universal coupler 1010.

In this embodiment, the set-top box housing 1002 encloses the processing chassis module 12, 602 so that the processing chassis module 12, 602 is part of the set-top box 1004. Similarly, the display unit housing 1006 encloses the presentation chassis module 14, 602 so that the presentation chassis module 14, 602 is part of the display unit 1008.

Advantageously, the set-to box 1004 (having the processing chassis module 12, 602 located therein) is lighter and easier to locate in an accessible location (its easier to grip and balance) than moving an entire television system having the processing 12, 602, and presentation chassis 14, 604 in a unitary-type housing. Thus, having the processing chassis module 12, 602 within the set-top box 1004 makes it easier for the user to connect peripheral devices, e.g, video recorders, computers, digital cameras, etc., to the television system 10. Furthermore, because of the mobility of the set-top box 1004, upgrading the processing chassis module 12, 602, within the set-top box 1004 is easier than upgrading a processing chassis module that shares a housing with a presentation chassis module. Additionally, upgrading the processing chassis module 12, 602, within the set-top box 1004, is safer because a person performing the upgrade need not worry about the higher voltages normally present with the presentation chassis module 14, 602.

The universal coupler 1010 comprises one of the interfaces 16, 628 as disclosed herein, and thus, comprises one or more communication lines for command signals, digital audio and video signals, and in some embodiments, the power line 612.

Based on the above discussion, it is apparent that the processing chassis module 12, 602 and presentation chassis module 14, 604 can be designed independently of one another. Moreover, because the processing chassis module 12, 602 and presentation chassis module 14, 604 can operate independently of one another, families of digital televisions can be created through the interchanging of various combinations of processing and presentation chassis modules with the global interface. For example, through the modular television architecture of the present invention, it is possible to match different types of processing chassis modules (e.g. based on functionality) with a single presentation chassis module. Thus, a family of digital televisions can be made available based on functionality or performance. Moreover, upgrading a particular digital television can be performed by simply exchanging one module with another module. This provides the digital television manufacturer with a powerful development tool as presentation chassis development is generally slower than processing chassis development. Correspondingly, when a new or upgraded presentation chassis module is available, it can be matched with any number of processing chassis modules to generate a new family of products.

The above detailed description of the invention has been provided for the purposes of illustration and description. Although the present invention has been described with respect to a specific embodiment, various changes and modifications to the embodiment may be suggested to persons of ordinary skill in the art, and it is intended that the present invention encompass such changes and modifications as fall within the scope of the claims appended hereto.

What is claimed is:

1. A modular television, comprising:
a processing chassis having a power supply and circuitry configured to convert an analog audiovisual signal into at least one digital audiovisual signal and provide an intermediate digital signal derived from the at least one digital signal;
a presentation chassis having a display and circuitry configured to receive the intermediate digital signal, convert the intermediate digital signal into a display signal, and provide the display signal to the display; and
an interface coupling the processing chassis and the presentation chassis comprising a single communication line configured to carry the intermediate digital signal.

2. The modular television of claim 1 wherein the processing chassis comprises circuitry configured to combine audio, video and digital data signals into the intermediate digital signal.

3. The modular television of claim 1 wherein the processing chassis includes circuitry to provide encrypted audio and video signals and combine the encrypted audio and video signals into the intermediate digital signal.

4. The modular television of claim 2 wherein the processing chassis and the presentation chassis are within separate housings.

5. The modular television of claim 1, wherein the presentation chassis comprises a power supply configured to receive power from a power line and provide operational power to the presentation chassis.

6. A method of making a modular television architecture, comprising:
placing a processing chassis in a housing, wherein the processing chassis is configured to convert an analog signal into at least one digital signal and provide an intermediate signal derived from the at least one digital signal;
placing a presentation chassis in the housing wherein the presentation chassis comprises a display and circuitry configured to receive the intermediate digital signal, convert the intermediate digital signal into a display signal, and provide the display signal to the display; and
coupling the processing chassis and the presentation chassis with a single communication line.

7. The method of claim 6 comprising the steps of:
placing a power supply within the processing chassis; and
coupling the power supply within the processing chassis with circuitry within the presentation chassis without placing an independent power supply in the presentation chassis.

8. The method of claim 6 wherein the step of placing a processing chassis in the housing includes placing encryption circuitry connected to the processing chassis in the housing configured to provide an intermediate digital signal comprising an encrypted video signal.

9. The method of claim 6 wherein the step of placing a processing chassis in a housing includes placing the processing chassis having circuitry to convert the analog signal into a digital video signal and a digital audio signal and combine the digital video and the digital audio signal into the intermediate digital signal.

10. A modular television, comprising:
processing means for providing power to a power output and receiving an analog signal comprising audiovisual content, converting the analog signal into a digital audio signal and a digital video signal and providing an intermediate digital signal derived from the digital audio and digital video signals to a communication output;
presentation means for providing a display in response to the intermediate digital signal from the interface means; and
interface means for receiving the intermediate digital signal from the communication output and the power from the power output and providing the intermediate digital signal and the power to the presentation means.

11. The modular television of claim 10 wherein the processing means includes means for encrypting the intermediate digital signal for decryption by the presentation means.

12. The modular television of claim 10, wherein the processing means comprises means for multiplexing the audio and video signals so that the intermediate digital signal is derived from multiplexed digital audio and digital video signals.

13. The modular television of claim 12, wherein the processing means comprises means for encrypting the intermediate digital signal for decryption by the presentation means.

14. The modular television of claim 10, wherein the processing means and the presentation means are enclosed by separate housings.

15. The modular television of claim 12, wherein the processing means comprises means for multiplexing digital data signals so that the intermediate digital signal is derived from multiplexed digital audio, digital video and digital data signals.

16. A digital television architecture, comprising:
a processing chassis configured to convert an analog input signal into at least one digital signal and to provide the at least one digital signal as an output, the processing chassis including a power supply;
a presentation chassis configured to receive the at least one digital signal and to convert audio and video components of the digital signal into a final signal for presentation on a display, the presentation chassis being separate from the processing chassis and including a dedicated power source of the presentation chassis being different from the power source of the processing chassis; and
an interface configured to provide a communication path for the at least one digital signal between the processing chassis and the presentation chassis.

17. The digital television architecture of claim 16, wherein the interface comprises separate audio and video communication lines for carrying respective audio and video components of the digital signal.

18. The digital television architecture of claim 17, wherein the processing chassis is configured to encrypt the video component of the digital signal.

19. The digital television architecture of claim 18, wherein the analog input signal is provided to the processing chassis by a communications channel selected from the group consisting of a terrestrial antenna, a cable connection, and a satellite connection.

20. The digital television of claim 16, wherein the processing chassis and the presentation chassis are within one housing.
